(19) United States
(12) Patent Application Publication
(10) Pub. No.: US 2019/0385828 A1
(43) Pub. Date: Dec. 19, 2019

(54) TEMPERATURE CONTROL SYSTEMS AND METHODS FOR REMOVING METAL OXIDE FILMS

(71) Applicant: LAM RESEARCH CORPORATION, Fremont, CA (US)

(72) Inventors: Akhil N. Singhal, Beaverton, OR (US); Patrick A. Van Cleemput, West Linn, OR (US); Jeong Seok Ha, Portland, OR (US)

(21) Appl. No.: 16/012,120

(22) Filed: Jun. 19, 2018

(51) Int. Cl. H01J 37/32; H01L 21/67; H01L 21/311; H01L 21/02

(52) U.S. Cl. CPC H01J 37/32871; H01L 21/67103; H01L 21/31122; H01L 21/02175; C23C 16/56; H01J 37/32724; H01J 37/32522; H01J 2237/2001; H01J 2237/334; H01L 21/02274

(57) ABSTRACT

A processing method includes: loading, onto a substrate support of a processing chamber, a substrate having a metal oxide film deposited on a surface of the substrate; based on a predetermined temperature, controlling a temperature of coolant provided to coolant channels through the substrate support, where the predetermined temperature is less than 50 degrees Celsius; and, while controlling the temperature of the coolant based on the predetermined temperature, selectively etching the metal oxide film including: flowing molecular hydrogen into the processing chamber; and striking plasma within the processing chamber.

### FIELD

The present disclosure relates to plasma chambers and more particularly to temperature control systems and methods for removal of metal oxide films to prevent powder formation.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates, such as semiconductor wafers. Example processes that may be performed on a substrate include, but are not limited to, deposition, etching, cleaning, and other types of processes. A substrate may be arranged on a substrate support, such as a pedestal or an electrostatic chuck (ESC), in a processing chamber. During processing, gas mixtures may be introduced into the processing chamber and plasma may be used to initiate chemical reactions.

A temperature of a substrate (e.g., a semiconductor wafer) in a processing chamber can be controlled. For example, one or more heaters can be arranged in the substrate support assembly, and the power supplied to the heaters can be controlled to control the temperature of a substrate on the substrate support. Additionally or alternatively, one or more fluids can be circulated through one or more flow passages in the substrate support using valves to heat and/or cool the substrate and the substrate support.

### SUMMARY

In a feature, a processing method includes: loading, onto a substrate support of a processing chamber, a substrate having a metal oxide film deposited on a surface of the substrate; based on a predetermined temperature, controlling a temperature of coolant provided to coolant channels through the substrate support, where the predetermined temperature is less than 50 degrees Celsius; and while controlling the temperature of the coolant based on the predetermined temperature, selectively etching the metal oxide film including: flowing molecular hydrogen into the processing chamber; and striking plasma within the processing chamber.

In further features, the metal oxide film is a tin oxide film.

In further features, the predetermined temperature is less than a temperature of the coolant during deposition of the metal oxide film on the substrate.

In further features, the predetermined temperature is less than or equal to 30 degrees

Celsius.

In further features, the predetermined temperature is less than or equal to 25 degrees

Celsius.

In further features: the processing chamber is located within a room; and the predetermined temperature is less than a temperature within the room.

In further features, selectively etching the metal oxide film further includes pumping gas out of the processing chamber.

In further features, flowing molecular hydrogen into the processing chamber includes flowing only molecular hydrogen into the processing chamber.

In a feature, a processing method includes: based on a predetermined temperature, supplying coolant to at least one of: coolant channels through a substrate support of a processing chamber; and coolant channels surrounding the processing chamber, where the predetermined temperature is less than 50 degrees Celsius; and while supplying the coolant based on the predetermined temperature, removing a metal oxide film from within the processing chamber including: flowing molecular hydrogen into the processing chamber; and striking plasma within the processing chamber.

In further features, the metal oxide film is a tin oxide film.

In further features, the predetermined temperature is less than or equal to 30 degrees Celsius.

In further features, the predetermined temperature is less than or equal to 25 degrees Celsius.

In further features: the processing chamber is located within a room; and the predetermined temperature is less than a temperature within the room.

In further features, the processing method further includes: loading, onto the substrate support of the processing chamber, a substrate; and depositing the metal oxide film on a surface of the substrate.

In further features, the processing method further includes, during the deposition of the metal oxide film on the surface of the substrate, supplying the coolant based on a second predetermined temperature that is greater than the predetermined temperature.

In further features, removing the metal oxide film further includes pumping gas out of the processing chamber.

In further features, flowing molecular hydrogen into the processing chamber includes flowing only molecular hydrogen into the processing chamber.

In a feature, a substrate processing system includes a processing chamber and a controller. The processing chamber includes a substrate support. The controller is configured to: based on a predetermined temperature, control a temperature of coolant provided to coolant channels through the substrate support, where the predetermined temperature is less than 50 degrees Celsius; and while controlling the temperature of the coolant based on the predetermined temperature, selectively etching a metal oxide film deposited on a surface of a substrate arranged on the substrate support, the selectively etching including: flowing molecular hydrogen into the processing chamber; and striking plasma within the processing chamber.

In further features, the metal oxide film is a tin oxide film.

In further features, the predetermined temperature is less than a temperature of the coolant during deposition of the metal oxide film on the substrate.

In further features, the predetermined temperature is less than or equal to 30 degrees Celsius.

In further features, the predetermined temperature is less than or equal to 25 degrees Celsius.

In further features: the processing chamber is located within a room; and the predetermined temperature is less than a temperature within the room.

In further features, the controller is further configured to pump gas out of the processing chamber.

In further features, the controller is configured to flow only molecular hydrogen into the processing chamber.

In a feature, a substrate processing system includes: a processing chamber including a substrate support; and a controller. The controller is configured to: based on a predetermined temperature, supplying coolant to at least one of: coolant channels through the substrate support; and coolant channels surrounding the processing chamber, where the predetermined temperature is less than 50 degrees Celsius; and, while supplying the coolant based on the predetermined temperature, remove a metal oxide film from within the processing chamber including: flowing molecular hydrogen into the processing chamber; and striking plasma within the processing chamber.

In further features, the metal oxide film is a tin oxide film.

In further features, the predetermined temperature is less than or equal to 30 degrees Celsius.

In further features, the predetermined temperature is less than or equal to 25 degrees Celsius.

In further features: the processing chamber is located within a room; and the predetermined temperature is less than a temperature within the room.

In further features, the controller is further configured to: deposit the metal oxide film on a surface of a substrate arranged on the substrate support.

In further features, the controller is further configured to, during the deposition of the metal oxide film on the surface of the substrate, supply the coolant based on a second predetermined temperature that is greater than the predetermined temperature.

In further features, the controller is further configured to pump gas out of the processing chamber.

In further features, the controller is configured to flow only molecular hydrogen into the processing chamber.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 includes a functional block diagram of an example substrate processing system;

FIG. 2 includes a functional block diagram including an example cooling system including a coolant assembly;

FIG. 3 includes a flowchart depicting an example method for depositing a metal oxide film on substrates within a processing chamber and periodically cleaning the metal oxide film from within the processing chamber without turning the metal oxide film into powder;

FIG. 4 includes a flowchart depicting an example method for etching a metal oxide film deposited on substrates without turning the metal oxide film into powder;

FIG. 5 includes an example graph of thickness of metal oxide on substrates versus temperature at which etching of the metal oxide was performed; and

FIG. 6 includes example illustrations of surfaces of substrates after etching of metal oxide film at various different temperatures and some areas the substrates were wiped.

In the drawings, reference numbers may be reused to identify similar and/or identical elements.

### DETAILED DESCRIPTION

Coolant can be used to regulate the temperature of a substrate arranged on a substrate support within a processing chamber. For example, during deposition of a metal oxide film, coolant can be supplied at a first predetermined temperature to coolant channels in a base portion of the substrate support and/or to coolant channels or tubes surrounding the processing chamber. During etching of the metal oxide film from the substrate and/or during cleaning of interior surfaces of the processing chamber, coolant can be supplied at a second predetermined temperature to the coolant channels or tubes.

The second predetermined temperature is less than the first predetermined temperature. If the second predetermined temperature is too high, however, all or a portion of the metal oxide film may decompose into powder (e.g., metal hydrides) during the etching or cleaning. Removal of all of the powder from the processing chamber is difficult and time consuming. If left in the processing chamber, the powder may increase defect counts of one or more substrates that are later processed within the processing chamber.

According to the present disclosure, the second predetermined temperature is reduced to a predetermined temperature to ensure that the metal oxide film remains volatile (and does not transition into powder) during etching and/or cleaning of the processing chamber. If the metal oxide remains volatile, it can be vaporized and pumped out of the processing chamber.

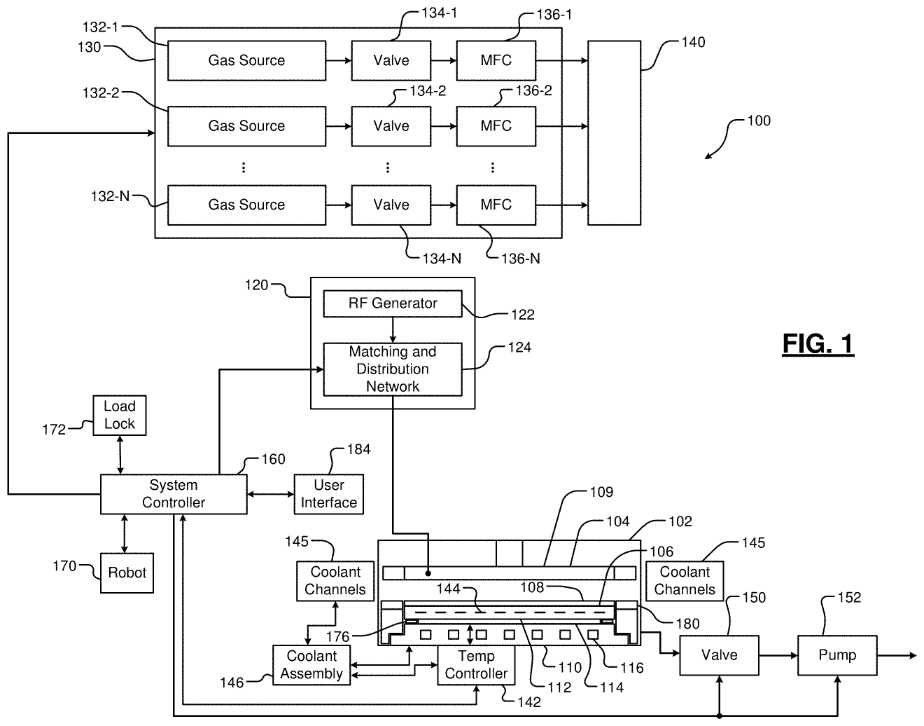

Referring now to FIG. 1, a functional block diagram of an example substrate processing system 100 is shown. For example only, the substrate processing system 100 may be used for chemical vapor deposition (CVD), plasma enhanced CVD (PECVD), atomic layer deposition (ALD), plasma enhanced ALD (PEALD), etching, and/or one or more types of processing.

The substrate processing system 100 includes a processing chamber 102 that encloses components of the substrate processing system 100 and contains radio frequency (RF) plasma. While an example of the substrate processing system 100 and the processing chamber 102 are shown as an example, the present disclosure is also applicable to other types of substrate processing systems and processing chambers, such as a substrate processing system that generates plasma in-situ, that implements remote plasma generation and delivery (e.g., using a plasma tube, a microwave tube), etc. In various implementations, deposition may be performed within one processing chamber and etching may be performed in another processing chamber.

The processing chamber 102 includes an upper electrode 104 and a substrate support 106, such as an electrostatic chuck (ESC). A substrate 108 is arranged on the substrate support 106 and one or more plasma processes are performed on the substrate 108. For example, a metal oxide film may be deposited on the substrate 108. Additionally or alternatively, etching of the metal oxide film previously deposited on the substrate 108 may be performed. The metal oxide film may be tin oxide or another suitable metal oxide film.

The metal oxide film deposited onto substrates may also build up on the processing chamber 102 (e.g., components of the processing chamber 102 and interior surfaces of the processing chamber 102) over time as substrates are processed. Cleaning cycles of the processing chamber 102 may be performed periodically (e.g., each M number of substrates, where M is an integer greater than one) to remove (or clean) metal oxide film from within the processing chamber 102.

Etching of the metal oxide film deposited on substrates and cleaning of the metal oxide film from within the processing chamber 102 is performed using plasma and a molecular hydrogen (H₂) (i.e., using hydrogen as the etchant). The etching and cleaning could be performed using fluorine, chlorine, bromine, and/or iodine plasma chemistries. Use of chorine, bromine, and/or iodine, however, may react with and/or damage the processing chamber 102 and one or more components (e.g., aluminum components) within the processing chamber 102.

The upper electrode 104 may include a gas distribution device, such as a showerhead 109, that introduces and distributes process gases within the processing chamber 102. The showerhead 109 may include a stem portion including one end connected to a top surface of the processing chamber 102. A base portion is generally cylindrical and extends radially outwardly from an opposite end of the stem portion at a location that is spaced from the top surface of the processing chamber 102. A substrate-facing surface, or faceplate, of the base portion of the showerhead 109 includes a plurality of holes through which process gas or purge gas flows. Alternately, the upper electrode 104 may include a conducting plate and the process gases may be introduced in another manner.

The substrate support 106 may include an electrically conductive baseplate 110 that acts as a lower electrode. The baseplate 110 supports a ceramic layer 112. A thermal resistance layer 114 (e.g., a bond layer) may be arranged between the ceramic layer 112 and the baseplate 110. The baseplate 110 may include one or more coolant channels 116 for flowing coolant through the baseplate 110. In some examples, a protective seal 176 may be provided around a perimeter of the thermal resistance layer 114 between the ceramic layer 112 and the baseplate 110.

An RF generating system 120 generates and outputs an RF voltage to one of the upper electrode 104 and the lower electrode (e.g., the baseplate 110 of the substrate support 106) to strike and maintain plasma. The other one of the upper electrode 104 and the baseplate 110 may be DC grounded, AC grounded, or floating. For example only, the RF generating system 120 may include an RF voltage generator 122 that generates the RF voltage that is fed by a matching and distribution network 124 to the upper electrode 104 or the baseplate 110. In other examples, the plasma may be generated inductively or remotely. Although, as shown for example purposes, the RF generating system 120 corresponds to a capacitively coupled plasma (CCP) system, the present disclosure is also applicable to other types of systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources 132 supply one or more deposition gasses, etch gases, carrier gases, inert gases, etc., and mixtures thereof.

For example, the gas sources 132 supply one or more gasses to deposit the metal oxide film. The gas sources 132 may additionally or alternatively supply one or more gasses (e.g., molecular hydrogen) for etching and/or cleaning of the metal oxide film. The gas sources 132 also supply purge gas.

The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 109 and output to the processing chamber 102 from the showerhead 109.

A temperature controller 142 is connected to a plurality of heating elements, such as thermal control elements (TCEs) 144 arranged in the ceramic layer 112. For example, the TCEs 144 may include, but are not limited to, macro heating elements corresponding to respective zones in a multi-zone heating plate and/or an array of micro heating elements disposed across multiple zones of a multi-zone heating plate. The TCEs 144 may be, for example, resistive heaters that generate heat when power is applied to the heaters, respectively, or another suitable type of heating element. The temperature controller 142 controls the TCEs 144 to control temperatures at various locations on the substrate support 106 and the substrate 108.

The temperature controller 142 also communicates with a coolant assembly 146 and controls coolant (fluid) flow through the coolant channels 116. The coolant may be liquid or gas. In some types of processing chambers, such as processing chambers within which deposition is performed, coolant may also be circulated through coolant channels 145 that surround the processing chamber. The coolant channels 145 can be coolant channels 145 formed in walls of the processing chamber 102 and/or coolant conduits (e.g., tubes) that surround the processing chamber 102. In processing chambers within which etching is performed, the coolant channels 145 may be implemented or omitted.

The temperature controller 142 operates the coolant assembly 146 to selectively flow the coolant through the coolant channels 116 and/or coolant channels 145 to cool the substrate support 106 and/or the processing chamber 102. The temperature controller 142 may control the TCEs 144 together with the coolant assembly 146, for example, to achieve one or more target temperatures and/or one or more target coolant flowrates during one or more processes.

A valve 150 and pump 152 may be used to evacuate (purge) reactants and other gasses from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160.

In some examples, the substrate support 106 includes an edge ring 180. The edge ring 180 may be moveable (e.g., moveable upward and downward in a vertical direction) relative to the substrate 108. For example, movement of the edge ring 180 may be controlled via an actuator responsive to the system controller 160. In some examples, a user may input control parameters to the system controller 160 via a user interface 184, which may include one or more input mechanisms, a display, etc.

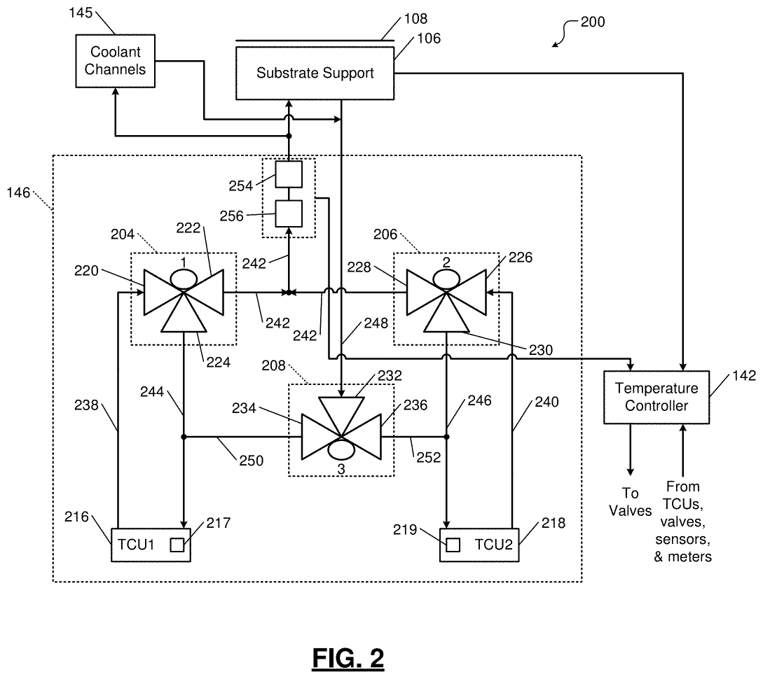

FIG. 2 includes a functional block diagram including an example cooling system 200 including the coolant assembly 146. The cooling system 200 may include a first three-way proportional valve (hereinafter first valve) 204, a second three-way proportional valve (hereinafter second valve) 206, a third three-way proportional valve (hereinafter third valve) 208, and first and second temperature control units (TCUs) (coolant sources) 216 and 218. The first TCU 216 supplies a coolant at a first temperature. The second TCU 218 supplies the coolant at a second temperature. While the example of two TCUs is provided, only one TCU may be implemented or more than two TCUs may be implemented.

In some implementations, the flow rate of each of the first and second TCUs 216 and 218 may be fixed. The flow rates of the first and second TCUs 216 and 218 may be the same or different. For example, the first TCU 216 may have a first fixed flow rate, and the second TCU 218 may have a second fixed flow rate that is the same as or different than the first fixed flow rate. The first and second TCUs 216 and 218 each include a pump. The pump of the first TCU 216 pumps coolant to the first valve 204, and the pump of the second TCU 218 pumps coolant to the second valve 206. The first and second TCUs 216 and 218 each also include one or more heating devices (e.g., electric heaters) and/or one or more cooling devices (e.g., chillers) that heat and/or cool coolant within the first and second TCUs 216 and 218.

The first valve 204 has an input port 220, a first output port 222, and a second output port (or bypass) 224. The second valve 206 has an input port 226, a first output port 228, and a second output port (or bypass) 230. The third valve 208 has an input port 232, a first output port 234, and a second output port 236.

The input port 220 of the first valve 204 receives the coolant at the first temperature from the first TCU 216 at the first fixed flow rate via a first fluid line 238. The input port 226 of the second valve 206 receives the coolant at the second temperature from the second TCU 218 at the second fixed flow rate via a second fluid line 240.

The first output port 222 of the first valve 204 outputs a first portion of the coolant received from the first TCU 216 into a supply line 242. The first output port 228 of the second valve 206 outputs a first portion of the coolant received from the second TCU 218 into the supply line 242. The first portions of the coolant output from the respective first output ports 222 and 228 of the first and second valves 204 and 206 are mixed in the supply line 242. The mixed coolant in the supply line 242 is supplied to the substrate support 106 and/or coolant channels surrounding the processing chamber 102.

The temperature controller 142 controls the first and second valves 204 and 206 and thereby controls the amounts of the first portions of the coolant that are output from the respective first output ports 222 and 228 of the first and second valves 204 and 206 to the supply line 242. The temperature controller 142 controls the first and second valves 204 and 206 and determines the amounts based on a target (or setpoint) temperature.

In various implementations, the temperature controller 142 may set the target temperature specific based on the process performed. For example, the temperature controller 142 may set the target temperature to a first predetermined temperature that is greater than a temperature of the room in which the processing chamber 102 is located during deposition of the metal oxide film (e.g., tin oxide) on the substrate 108. The first predetermined temperature may be approximately 125 degrees Celsius or another suitable temperature for deposition of the metal oxide film on substrates. The temperature of the room may be, for example, approximately 30 degrees Celsius or another suitable temperature. As used herein, approximately may mean+/−10 percent of the associated value.

The temperature controller 142 set the target temperature to a second predetermined temperature during etching of the metal oxide film on the substrate 108 and during cleaning of the processing chamber 102 within which the metal oxide film was deposited. The second predetermined temperature is calibrated and may be, for example, less than or equal to approximately 50 degrees Celsius, less than or equal to approximately 30 degrees Celsius, or less than or equal to approximately 25 degrees Celsius. The second predetermined temperature may be less than the temperature of the room in which the processing chamber 102 is located. The second predetermined temperature is calibrated such that the metal oxide film vaporizes and does not transition into powder (e.g., metal hydrides that decompose into powder at room temperature or higher) during etching of the metal oxide film and/or during cleaning of the processing chamber.

A second (remainder) portion of the coolant received by the first valve 204 from the first TCU 216 may be returned to the first TCU 216 via the second output port (or bypass) 224 of the first valve 204 via a fluid line 244. A second (remainder) portion of the coolant received by the second valve 206 from the second TCU 218 may be returned to the second TCU 218 via the second output port (or bypass) 230 of the second valve 206 via a fluid line 246.

Since the second portions of the coolant received by the first and second valves 204 and 206 are returned to the first and second TCUs 216 and 218, the first and second TCUs 216 and 218 can supply the coolant to the first and second valves 204 and 206 at the respective fixed flow rates. This may simplify the design of the first and second TCUs 216 and 218. For example, the pumps of the first and second TCUs 216 and 218 can be operated at single speeds. While operating at the single speeds, the target temperature may be achieved via adjusting the openings of the first and/or second valves 204 and 206.

The coolant output from the substrate support 106 and/or the coolant channels surrounding the processing chamber 102 is received by the input port 232 of the third valve 208 via a return line 248. The third valve 208 divides the returned coolant between the first and second TCUs 216 and 218.

A first portion of the coolant received by the third valve 208 from the substrate support 106 is returned to the first TCU 216 via the first output port 234 of the third valve 208 through a fluid line 250 and the fluid line 244. A second portion of the coolant received by the third valve 208 from the substrate support 106 is returned to the second TCU 218 via the second output port 236 of the third valve 208 through a fluid line 252 and the fluid line 246.

The temperature controller 142 controls the third valve 208 and determines the appropriate or target amounts of the first and second portions of the coolant that are output from the first and second output ports 234 and 236 of the third valve 208 to the first and second TCUs 216 and 218, respectively. For example, the temperature controller 142 monitors the level of the coolant in the first and second TCUs 216 and 218 based on data received from level sensors 217 and 219 in the first and second TCUs 216 and 218. The temperature controller 142 determines the level of the coolant in each of the first and second TCUs 216 and 218 and determines the amounts of the first and second portions of the coolant to return to the first and second TCUs 216 and 218 based on the levels.

A temperature sensor 254 (e.g., a thermocouple) senses the temperature of the coolant supplied to the substrate support 106 and/or the coolant channels 145 through the supply line 242. A flow rate sensor (e.g., a flow meter) 256 measures a flow rate of the coolant supplied to the substrate support 106 and/or the coolant channels 145 through the supply line 242. While not shown, a second temperature sensor and a second flow meter can be coupled to the return line 248 and measure a temperature and a flow rate of the coolant returned from the substrate support 106 and/or the coolant channels 145 through the return line 248.

The temperature controller 142 may include a proportional integral derivative (PID) controller or another suitable type of closed loop controller. The temperature controller 142 controls the amount of coolant supplied by the first and second valves 204 and 206 based on the target temperature at which the coolant is to be supplied to the substrate support 106 and/or the coolant channels surrounding the processing chamber 102. For example, the temperature controller 142 may control the first and second valves 204 and 206 to adjust the temperature measured by the temperature sensor 254 toward or to the target temperature.

Additionally, the temperature controller 142 controls the amount of coolant supplied by the first and second valves 204 and 206 based on a target flow rate at which the coolant is to be supplied to the substrate support 106 and/or the coolant channels 145. For example, the temperature controller 142 may control the first and second valves 204 and 206 to adjust the flowrate measured by the flow rate sensor 256 toward or to the target flow rate.

Via the coolant assembly 146, the temperature of coolant output may be switched from the first predetermined temperature to the second predetermined temperature in less than a predetermined switching period. The temperature of coolant can also be switched from the second predetermined temperature to the first predetermined temperature in less than the predetermined switching period.

The predetermined switching period may be, for example, approximately 15 minutes or another suitable period. The temperature of the coolant may be switched from the first predetermined temperature to the second predetermined temperature, for example, to transition from depositing the metal oxide film on substrates to cleaning the metal oxide film from the processing chamber 102 or etching the metal oxide film deposited on a substrate. The temperature of the coolant may be switched from the second predetermined temperature, for example, to transition from cleaning the metal oxide film from the processing chamber 102 or from etching the metal oxide film deposited on a substrate to depositing the metal oxide film on substrates.

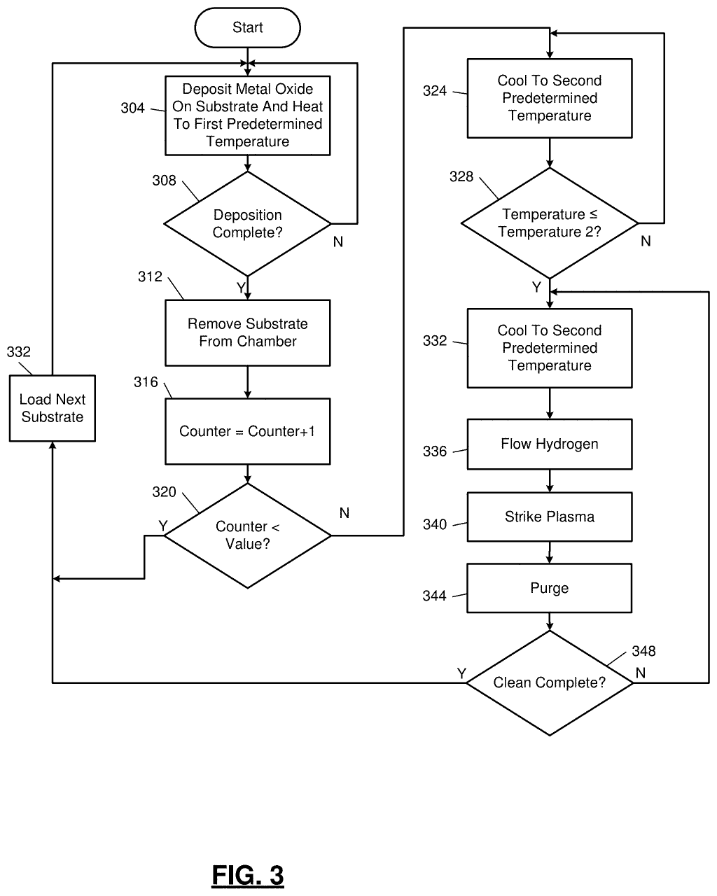

FIG. 3 includes an example method for depositing the metal oxide film on substrates within the processing chamber 102 and periodically cleaning the processing chamber 102. Control begins with 304 where the system controller 160 controls the gas delivery system 130 and the RF generating system 120 to deposit the metal oxide film (e.g., tin oxide) on a substrate on the substrate support 106 within the processing chamber 102 via plasma. The temperature controller 142 controls the temperature of coolant supplied to the substrate support 106 and/or the coolant channels 145 to the first predetermined temperature during the deposition of the metal oxide film on the substrate. As discussed above, the first predetermined temperature is greater than the temperature of the room that the processing chamber 102 is in.

At 308, the system controller 160 determines whether deposition of the metal oxide film on the substrate is complete. For example, the system controller 160 may determine whether a period of the deposition of the metal oxide film on the substrate is greater than a predetermined deposition period. If 308 is true, control continues with 312. If 308 is false, control may return to 304 and continue the deposition of the metal oxide film on the substrate.

At 312, the robot 170 may remove the substrate from the processing chamber 102. The robot 170 or another robot may move the substrate to another processing chamber for etching of the metal oxide film. In various implementations, etching of the metal oxide film may also be performed within the processing chamber 102 before the substrate is removed from the processing chamber 102.

At 316, the system controller 160 may increment a counter value (e.g., add 1 to the counter value). The counter value therefore corresponds to the number of substrates upon which the metal oxide film has been deposited within the processing chamber 102 since the processing chamber 102 was last cleaned to remove the metal oxide film from within the processing chamber 102.

The system controller 160 may determine whether the counter value is less than a predetermined value at 320. The predetermined value may be calibrated and is an integer greater than one. The predetermined value corresponds to the number of substrates to be processed (with the metal oxide film being deposited on the substrates) between consecutive cleaning cycles of the processing chamber 102. If 320 is true, the robot 170 or another robot may load a next substrate onto the substrate support 106 within the processing chamber 102 at 332, and control may return to 304 to begin deposition of the metal oxide film on the next substrate. If 320 is false, control may continue with 324. In various implementations, cleaning cycles of the processing chamber 102 may additionally or alternatively be performed each predetermined period of time and/or in response to user input to perform cleaning.

At 324, the temperature controller 142 controls the coolant assembly 146 to provide coolant to the substrate support 106 and/or the coolant channels 145 at the second predetermined temperature for cleaning. At 328, the system controller 160 may determine whether the temperature of coolant supplied to the substrate support 106 and/or the coolant channels 145 is less than or equal to the second predetermined temperature. If 328 is true, control continues with 332. If 328 is false, control may return to 324 to continue cooling the substrate support 106 and/or the processing chamber 102. In various implementations, 328 may be omitted.

At 332, cleaning begins and the temperature controller 142 continues to control the coolant assembly 146 to provide coolant to the substrate support 106 and/or the coolant channels 145 at the second predetermined temperature for cleaning. At 336, the system controller 160 controls the gas delivery system 130 to provide molecular hydrogen H₂ (e.g., only molecular hydrogen) to the processing chamber 102 to clean the metal oxide film (e.g., tin oxide) from within the processing chamber 102. At 340, the system controller 160 also controls the RF generating system 120 to strike plasma within the processing chamber 102 to clean the metal oxide film (e.g., tin oxide) from within the processing chamber 102. By cooling the substrate support 106 and/or the coolant channels 145 to the second predetermined temperature during the cleaning, the metal oxide vaporizes. This minimizes an amount of the metal oxide that is turned into powder.

Vaporized metal oxide can be evacuated from the processing chamber 102 via operation of the pump 152. At 344, the system controller 160 opens the valve 150 and turns on the pump 152 to purge the vaporized metal oxide from the processing chamber 102.

If formed, the powder may not be as completely removed via operation of the pump 152 and may be removed via additional (e.g., manual) cleaning of the processing chamber 102. If the powder is not removed from within the processing chamber 102, the powder may increase defect counts of substrates processed later within the processing chamber 102.

At 348, the system controller 160 determines whether the cleaning is complete. For example, the system controller 160 may determine whether a period since the cleaning began (e.g., since a first instance of 332) is greater than a predetermined cleaning period. If 348 is true, control may transfer to 332, as discussed above. If 348 is false, control may return to 332 and continue the cleaning of the processing chamber 102.

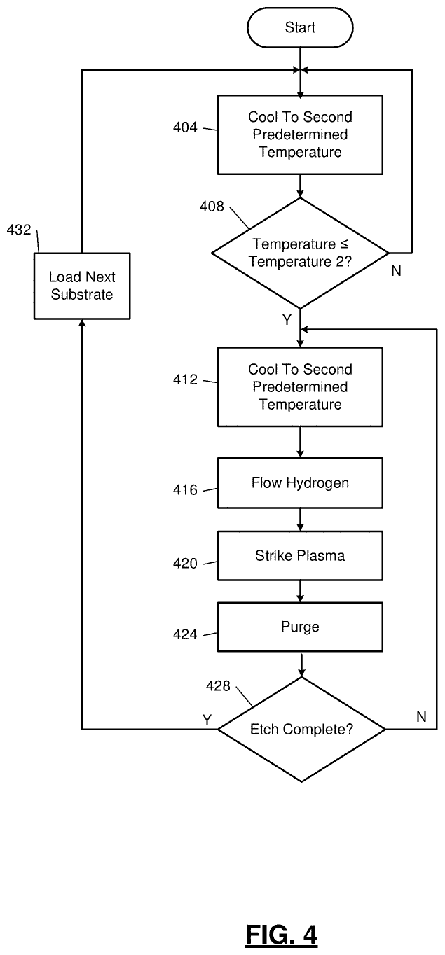

FIG. 4 includes an example method for etching the metal oxide film on substrates within the processing chamber 102 while cooling the substrates to prevent the metal oxide film from turning into powder. Control begins with a substrate (with the metal oxide film) located on the substrate support 106 within the processing chamber 102. At 404, the temperature controller 142 controls the coolant assembly 146 to provide coolant to the substrate support 106 and/or the coolant channels 145 at the second predetermined temperature for etching of the substrate.

At 408, the system controller 160 may determine whether the temperature of coolant supplied to the substrate support 106 and/or the coolant channels 145 is less than or equal to the second predetermined temperature. If 408 is true, control continues with 412. If 408 is false, control may return to 404 to continue cooling the substrate support 106 and/or the processing chamber 102. In various implementations, 408 may be omitted.

At 412, etching begins and the temperature controller 142 continues to control the coolant assembly 146 to provide coolant to the substrate support 106 and/or the coolant channels 145 at the second predetermined temperature for etching. At 416, the system controller 160 controls the gas delivery system 130 to provide molecular hydrogen H₂ (e.g., only molecular hydrogen) to the processing chamber 102 to etch the metal oxide film (e.g., tin oxide) from the substrate.

At 420, the system controller 160 controls the RF generating system 120 to strike plasma within the processing chamber 102 to etch the metal oxide film (e.g., tin oxide) from the substrate. By cooling the substrate support 106 and/or the coolant channels 145 to the second predetermined temperature during the etching, the metal oxide vaporizes. This minimizes an amount of the metal oxide that is turned into powder.

Vaporized metal oxide can be evacuated from the processing chamber 102 via operation of the pump 152. At 424, the system controller 160 opens the valve 150 and turns on the pump 152 to purge the vaporized metal oxide from the processing chamber 102.

At 428, the system controller 160 determines whether etching of the metal oxide film on the substrate is complete. For example, the system controller 160 may determine whether a period since the etching of the metal oxide film on the substrate began (e.g., since a first instance of 412) is greater than a predetermined etching period. If 428 is true, control continues with 432. If 428 is false, control may return to 412 and continue the etching.

At 432, the robot 170 or another robot may remove the substrate from the processing chamber 102. The robot 170 or another robot may move the substrate to another processing chamber for additional processing. Alternatively, additional processing may be performed on the substrate within the processing chamber 102. The robot 170 or another robot may also load a next substrate onto the substrate support 106 within the processing chamber 102 and control may return to 404 to begin etching of the metal oxide film from the next substrate.

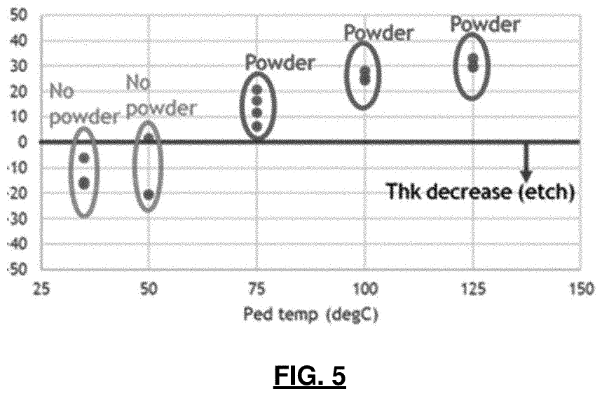

FIG. 5 includes an example graph of thickness of the metal oxide on substrates versus temperature at which etching of the metal oxide film on the substrates was performed. Zero (0) thickness corresponds to the initial thickness of the metal oxide film before etching is performed. As shown, when etching was performed while using temperatures less than 50 degrees Celsius, the thickness of the metal oxide film generally decreased due to the etching. In this case, the metal oxide film was vaporized and removed (without powder formation), thus causing a decrease in the thickness of the metal oxide present on the substrates.

When etching was performed while using temperatures greater than 50 degrees Celsius, however, the thickness of the metal oxide increased. The increase is attributable to the metal oxide film transitioning from film into powder and the powder remaining on the substrates as a result of the etching.

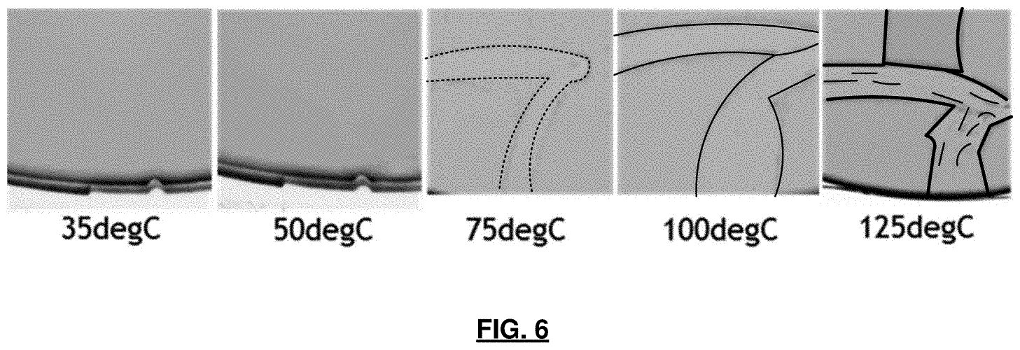

FIG. 6 includes example illustrations of surfaces (e.g., substrates, interior surfaces of processing chambers) after cleaning or etching of the metal oxide film at various different temperatures. In each case, only some areas the surfaces were wiped (e.g., by hand).

As shown, when etching or cleaning was performed while using temperatures less than 50 degrees Celsius, evidence of the wiping was not visible. Thus, use of temperatures less than 50 degrees Celsius did not cause the metal oxide film to transition into powder. Instead, the metal oxide was vaporized and removed.

When etching or cleaning was performed while using temperatures greater than 50 degrees Celsius, however, evidence of the wiping was visible. The visibility of the wiping increased as the temperature used increased. This indicates an increase in the metal oxide film transitioning from film into powder as the temperature used increased.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A processing method comprising:
loading, onto a substrate support of a processing chamber, a substrate having a metal oxide film deposited on a surface of the substrate;
based on a predetermined temperature, controlling a temperature of coolant provided to coolant channels through the substrate support,
wherein the predetermined temperature is less than 50 degrees Celsius; and
while controlling the temperature of the coolant based on the predetermined temperature, selectively etching the metal oxide film including:
flowing molecular hydrogen into the processing chamber; and
striking plasma within the processing chamber.

2. The processing method of claim 1 wherein the metal oxide film is a tin oxide film.

3. The processing method of claim 1 wherein the predetermined temperature is less than a temperature of the coolant during deposition of the metal oxide film on the substrate.

4. The processing method of claim 1 wherein the predetermined temperature is less than or equal to 30 degrees Celsius.

5. The processing method of claim 1 wherein the predetermined temperature is less than or equal to 25 degrees Celsius.

6. The processing method of claim 1 wherein:
the processing chamber is located within a room; and
the predetermined temperature is less than a temperature within the room.

7. The processing method of claim 1 wherein selectively etching the metal oxide film further includes pumping gas out of the processing chamber.

8. The processing method of claim 1 wherein flowing molecular hydrogen into the processing chamber includes flowing only molecular hydrogen into the processing chamber.

9. A processing method comprising:
based on a predetermined temperature, supplying coolant to at least one of:
coolant channels through a substrate support of a processing chamber; and
coolant channels surrounding the processing chamber,
wherein the predetermined temperature is less than 50 degrees Celsius; and
while supplying the coolant based on the predetermined temperature, removing a metal oxide film from within the processing chamber including:
flowing molecular hydrogen into the processing chamber; and
striking plasma within the processing chamber.

10. The processing method of claim 9 wherein the metal oxide film is a tin oxide film.

11. The processing method of claim 9 wherein the predetermined temperature is less than or equal to 30 degrees Celsius.

12. The processing method of claim 9 wherein the predetermined temperature is less than or equal to 25 degrees Celsius.

13. The processing method of claim 9 wherein:
the processing chamber is located within a room; and
the predetermined temperature is less than a temperature within the room.

14. The processing method of claim 9 further comprising:
loading, onto the substrate support of the processing chamber, a substrate; and
depositing the metal oxide film on a surface of the substrate.

15. The processing method of claim 14 further comprising during the deposition of the metal oxide film on the surface of the substrate, supplying the coolant based on a second predetermined temperature that is greater than the predetermined temperature.

16. The processing method of claim 9 wherein removing the metal oxide film further includes pumping gas out of the processing chamber.

17. The processing method of claim 9 wherein flowing molecular hydrogen into the processing chamber includes flowing only molecular hydrogen into the processing chamber.

18. A substrate processing system comprising:
a processing chamber including a substrate support; and
a controller configured to:
based on a predetermined temperature, control a temperature of coolant provided to coolant channels through the substrate support,
wherein the predetermined temperature is less than 50 degrees Celsius; and
while controlling the temperature of the coolant based on the predetermined temperature, selectively etching a metal oxide film deposited on a surface of a substrate arranged on the substrate support, the selectively etching including:
flowing molecular hydrogen into the processing chamber; and
striking plasma within the processing chamber.

19. The substrate processing system of claim 18 wherein the metal oxide film is a tin oxide film.

20. The substrate processing system of claim 18 wherein the predetermined temperature is less than a temperature of the coolant during deposition of the metal oxide film on the substrate.

21. The substrate processing system of claim 18 wherein the predetermined temperature is less than or equal to 30 degrees Celsius.

22. The substrate processing system of claim 18 wherein the predetermined temperature is less than or equal to 25 degrees Celsius.

23. The substrate processing system of claim 18 wherein:
the processing chamber is located within a room; and
the predetermined temperature is less than a temperature within the room.

24. The substrate processing system of claim 18 wherein the controller is further configured to pump gas out of the processing chamber.

25. The substrate processing system of claim 18 wherein the controller is configured to flow only molecular hydrogen into the processing chamber.

26. A substrate processing system comprising:
a processing chamber including a substrate support; and
a controller configured to:
based on a predetermined temperature, supplying coolant to at least one of:
coolant channels through the substrate support; and
coolant channels surrounding the processing chamber,
wherein the predetermined temperature is less than 50 degrees Celsius; and
while supplying the coolant based on the predetermined temperature, remove a metal oxide film from within the processing chamber including:
flowing molecular hydrogen into the processing chamber; and
striking plasma within the processing chamber.

27. The substrate processing system of claim 26 wherein the metal oxide film is a tin oxide film.

28. The substrate processing system of claim 26 wherein the predetermined temperature is less than or equal to 30 degrees Celsius.

29. The substrate processing system of claim 26 wherein the predetermined temperature is less than or equal to 25 degrees Celsius.

30. The substrate processing system of claim 26 wherein:
the processing chamber is located within a room; and
the predetermined temperature is less than a temperature within the room.

31. The substrate processing system of claim 26 wherein the controller is further configured to deposit the metal oxide film on a surface of a substrate arranged on the substrate support.

32. The substrate processing system of claim 31 wherein the controller is further configured to, during the deposition of the metal oxide film on the surface of the substrate, supply the coolant based on a second predetermined temperature that is greater than the predetermined temperature.

33. The substrate processing system of claim 26 wherein the controller is further configured to pump gas out of the processing chamber.

34. The substrate processing system of claim 26 wherein the controller is configured to flow only molecular hydrogen into the processing chamber.
